(19) United States
(12) Patent Application Publication
(10) Pub. No.: US 2021/0359033 A1
(43) Pub. Date: Nov. 18, 2021

(54) DISPLAY PANEL AND DISPLAY DEVICE

(71) Applicant: WUHAN CHINA STAR OPTOELECTRONICS SEMICONDUCTOR DSPLAY TECHNOLOGY CO., LTD., Wuhan (CN)

(72) Inventors: Yong ZHAO, Wuhan (CN); Yan XIE, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/622,938

(22) PCT Filed: May 20, 2019
(86) PCT No.: PCT/CN2019/087535

§ 371 Date: Dec. 16, 2019

(30) Foreign Application Priority Data
Apr. 25, 2019 (CN) 201910340413.7

(51) Int. Cl. H01L 27/32; H04N 5/225

(52) U.S. Cl. CPC H01L 27/3218; H01L 27/3216; H01L 27/3234; H04N 5/2257

(57) ABSTRACT

A display panel and a display device, include a light transmissive displaying region and main displaying region. The main displaying region surrounds the light transmissive displaying region. The display panel is constituted by rendering pixel units. The rendering pixel units includes first rendering pixel units disposed in the main displaying region and second rendering pixel units disposed in the light transmissive displaying region. The present invention lowers a density of the second rendering pixel units of the light transmissive displaying region to obtain better light transmittance such that the display device acquires better photographing effect. The second rendering pixel units in the light transmissive displaying region employs a traditional RGB sub-pixel arrangement to solve a color shift issue of a lowered density of the pixels of the light transmissive displaying region.

### FIELD OF INVENTION

The present invention relates to a field of displays, especially to a display panel and a display device.

### BACKGROUND OF INVENTION

With the continuous development of the mobile phone industry, functions on the display of mobile phones have increased accordingly. Displays of existing mobile phone have been generally equipped with a camera module. Because a camera device needs to be placed apart from the display screen, an available area for placement of the display screen decreases, which departs from a developing trend of greater screen ratio of smart display screens.

Nowadays, a camera module serves as an essential part of a cell phone. How to integrate the camera with the display screen to maximize the screen ratio is an urgent problem to be solved.

In the prior art, the front camera is usually designed on the outside of the display screen, and the display screen needs to be reduced in size to accommodate the front camera, so that the camera area of the whole machine cannot display the content normally, and finally most mobile phones can only be cut into an unusual shape.

Therefore, it is necessary to provide a new display panel and a new display device improving light transmittance and light transmissive uniformity of a display screen in a camera region and solving the incompatibility of a conventional display panel with the front camera.

### SUMMARY OF INVENTION

### Technical Solution

An objective of the present invention is to provide a display panel and a display device that by dividing the display panel into a main displaying region and a light transmissive displaying region, and lowering a density of second rendering pixel units of the light transmissive displaying region, acquires better light transmittance rate, which makes the display device to obtain better photographing effect. Furthermore, the second rendering pixel units in the light transmissive displaying region employs a traditional RGB sub-pixel arrangement to solve the color shift issue due to a lowered density of the second rendering pixel units in the light transmissive displaying region.

The present invention provides a display panel, comprising a light transmissive displaying region and a main displaying region, the main displaying region surrounding the light transmissive displaying region, and the display panel constituted by a plurality of rendering pixel units; wherein the rendering pixel units comprise a plurality of first rendering pixel units disposed in the main displaying region and a plurality of second rendering pixel units disposed in the light transmissive displaying region; wherein the first rendering pixel units employ a pentile arrangement to make the main displaying region illuminate and display; and wherein the second rendering pixel units employ a traditional RGB arrangement to make the light transmissive displaying region illuminate and display.

Furthermore, in the main displaying region, each of the first rendering pixel units comprises at least one first sub-pixel; and in the light transmissive displaying region, each of the second rendering pixel units comprises at least one second sub-pixel.

Furthermore, the first rendering pixel units are arranged in an array in the main displaying region; the second rendering pixel units are arranged in an array in the light transmissive displaying region; and an area of the first sub-pixel is greater than an area of the second sub-pixel.

Furthermore, a density of the second rendering pixel units is less than a density of the first rendering pixel units.

Furthermore, the first rendering pixel units are arranged in an array in the main displaying region; in the light transmissive displaying region, the second rendering pixel units are arranged in an array to form at least two rows of the second rendering pixel units; the rows of the second rendering pixel units comprise odd rows of the second rendering pixel units and even rows of the second rendering pixel units; and the odd rows of the second rendering pixel units are arranged alternately with the even rows of the second rendering pixel units.

Furthermore, the first sub-pixel is one of a red sub-pixel, a green sub-pixel and a blue sub-pixel; and the second sub-pixel is one of a red sub-pixel, a green sub-pixel, and a blue sub-pixel.

Furthermore, each of the second rendering pixel units comprises three second sub-pixels, which are a red sub-pixel, a green sub-pixel, and a blue sub-pixel.

Furthermore, each of the first rendering pixel units comprises two first sub-pixels, and each of the first rendering pixel units is disposed with a red sub-pixel and a green sub-pixel, or with a blue sub-pixel and the green sub-pixel, or with a blue sub-pixel and the red sub-pixel.

Furthermore, the display panel comprises: a substrate; a first electrode disposed on the substrate; a hole injection layer disposed on a side of the first electrode away from the substrate; a hole transport layer disposed on a side of the hole injection layer away from the first electrode; a first light emitting diode disposed on a side of the hole transport layer away from the hole injection layer; an electron transport layer disposed on a side of the first light emitting diode away from the hole transport layer; a second electrode disposed on a side of the electron transport layer away from the light emitting diode; and a first encapsulation layer disposed on a side of the second electrode away from the electron transport layer.

The present invention also provides a display device, comprising the display panel and a camera module, the camera module is disposed under the display panel and corresponds to the light transmissive displaying region.

### Advantages

The present invention provides a display panel and a display device, by dividing the display panel into a main displaying region and a light transmissive displaying region, and lowering a density of second rendering pixel units of the light transmissive displaying region, acquires better light transmittance rate, which makes the display device to obtain better photographing effect. Furthermore, the second rendering pixel units in the light transmissive displaying region employs a traditional RGB sub-pixel arrangement to solve the color shift issue due to a lowered density of the second rendering pixel units in the light transmissive displaying region.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may acquire other figures according to the appended figures without any creative effort.

FIG. 1 is a schematic plane view of a display panel of an embodiment of the present invention;

FIG. 2 is a schematic view of partial structures of a main displaying region of a display panel of an embodiment of the present invention;

FIG. 3 is a schematic view of partial structures of a light transmissive displaying region of a display panel of an embodiment of the present invention;

FIG. 4 is a schematic view of structures of a display panel of an embodiment of the present invention;

FIG. 5 is a schematic view of structures of the present invention display device;

FIG. 6 is a schematic view of partial structures of a light transmissive displaying region of a display panel of another embodiment of the present invention.

### DETAILED DESCRIPTION OF PREFERRED EMBODIMENTS

Each of the following embodiments is described with appending figures to illustrate specific embodiments of the present invention that are applicable. The terminologies of direction mentioned in the present invention, such as “upper”, “lower”, “front”, “rear”, “left”, “right”, “inner”, “outer”, “side surface”, etc., only refer to the directions of the appended figures. Therefore, the terminologies of direction are used for explanation and comprehension of the present invention, instead of limiting the present invention. In the figures, units with similar structures are marked with the same reference characters.

The present invention will be described in detail in many different forms, and the present invention should not be construed as merely the specific embodiment set forth herein. The present invention provides an embodiment for explaining the present invention. The practical application of the present invention will enable others skilled in the art to understand the various embodiments of the present invention and various modifications suitable for the particular intended application.

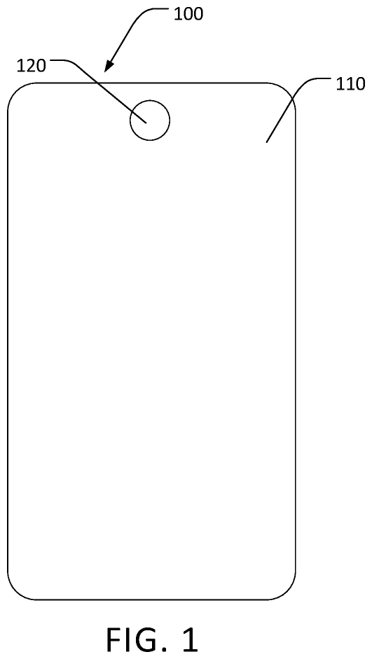

With reference to FIG. 1, in an embodiment of the present invention, a display panel 100 is provided and includes a light transmissive displaying region 120 and a main displaying region 110. The main displaying region 110 surrounds the light transmissive displaying region 120. The first rendering pixel units employ a pentile arrangement to make the main displaying region illuminate and display. The second rendering pixel units employ a traditional RGB arrangement to make the light transmissive displaying region illuminate and display. Therefore, the light transmissive displaying region 120 and the main displaying region 110 can both used for a displaying screen of the display panel 100 to achieve a true full screen.

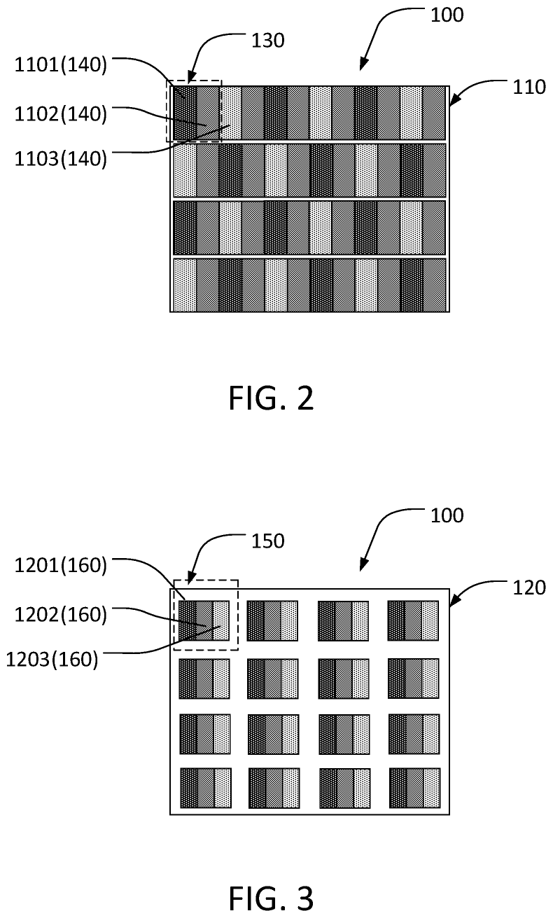

With reference to FIGS. 2 and 3, the display panel 100 is constituted by a plurality of rendering pixel units. The rendering pixel units includes a plurality of first rendering pixel units 130 disposed in the main displaying region 110 and a plurality of second rendering pixel units 150 disposed on the light transmissive displaying region 120.

In the main displaying region 110, each of the first rendering pixel units 130 includes at least one first sub-pixel 140. In the light transmissive displaying region 120, each of the second rendering pixel units 150 includes at least one second sub-pixel 160.

The first sub-pixel 140 is one of a red sub-pixel, a green sub-pixel, and a blue sub-pixel. The second sub-pixel 160 is one of a red sub-pixel, a green sub-pixel, and a blue sub-pixel.

The first rendering pixel units 130 are arranged in an array in the main displaying region 110. The second rendering pixel units 150 are arranged in an array in the light transmissive displaying region 120.

An area of the first sub-pixel 140 is greater than an area of the second sub-pixel 160. Thus, a density of the second rendering pixel units 150 can be made less than a density of the first rendering pixel units 130 to allow more ambient light to pass through the light transmissive displaying region 120.

In the present embodiment, the second rendering pixel units 150 include three second sub-pixels 160, the second rendering pixel units 150 are a red sub-pixel, a green sub-pixel, and a blue sub-pixel.

The first rendering pixel units 130 include two first sub-pixels 140, and the first rendering pixel units 130 include a red sub-pixel and a green sub-pixel; or a blue sub-pixel and the green sub-pixel; or a blue sub-pixel and the red sub-pixel.

In the present embodiment, reducing the area of the second sub-pixel 160 of the light transmissive displaying region 120 further makes the density of the second rendering pixel units 150 less than the density of the first rendering pixel units 130, which can effectively allow ambient light to pass therethrough to make the camera module to collect the ambient light. Furthermore, the second rendering pixel units 150 in the light transmissive displaying region 120 employ the RGB arrangement, which mitigates a color shift issue of the light transmissive displaying region 120 due to a lowered density of the pixels. Also, the light transmissive displaying region 120 can implement displaying of the display panel, which achieves full screen displaying.

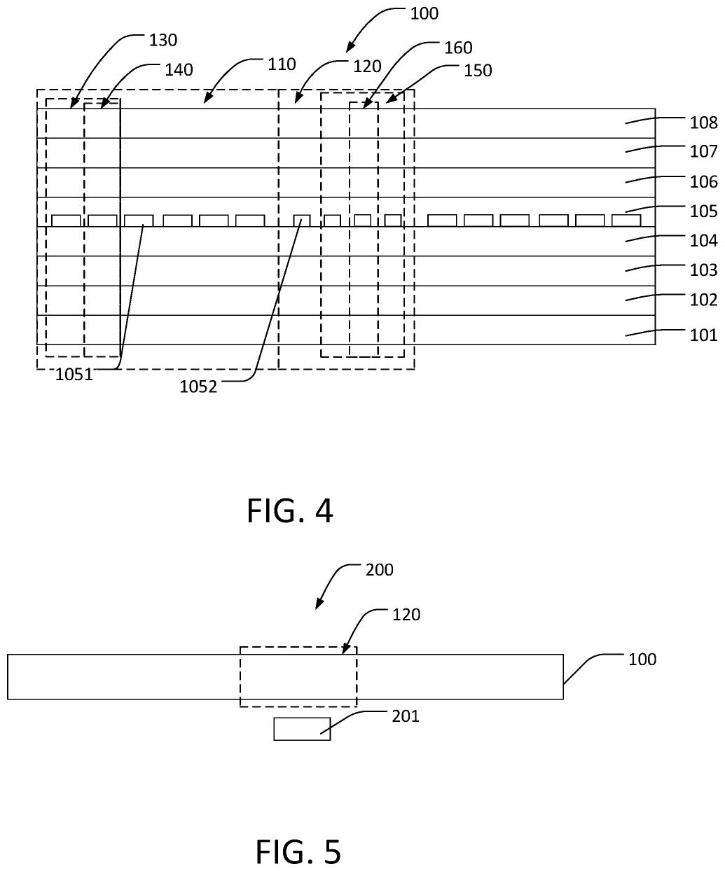

With reference to FIG. 4, the display panel 100 includes a first electrode 102, a hole injection layer 103, a hole transport layer 104, a light emitting diode 105, an electron transport layer 106, a second electrode 107, and a first encapsulation layer 108 that are disposed sequentially on the substrate 101.

The substrate 101 is a flexible substrate. Material of the substrate 101 is polyimide. The material of polyimide can make the substrate 101 of the present invention flexible.

The first electrode 102 is disposed on the substrate 101. The first electrode 102 is an anode, and the material of first electrode 102 is transparent indium tin oxide (ITO).

The hole injection layer 103 is disposed on a side of the first electrode 102 away from the substrate 101. The hole transport layer 104 is disposed on a side of the hole injection layer 103 away from the first electrode 102.

The light emitting diode 105 is disposed on a side of the hole transport layer 104 away from the hole injection layer 103. The light emitting diode 105 includes at least a first light emitting unit 1051. The light emitting unit 1051 is one of a red light emitting unit, a green light emitting unit, and a blue light emitting unit. The light emitting unit 1051 is configured to make different sub-pixels to emit light of different colors.

In the present embodiment, in the main displaying region 110, the light emitting diode 105 includes a plurality of first light emitting units 1051 arranged in an array. The first light emitting units 1051 include red light emitting units, green light emitting units, and blue light emitting units. The first light emitting units 1051 are conventional organic light emitting diode (OLED) light emitting unit. The first light emitting units 1051 make the first sub-pixel 140 to emit light of red, green or blue.

In the light transmissive displaying region 120, the light emitting diode 105 includes a plurality of second light emitting units 1052 arranged in an array. The second light emitting units 1052 include red light emitting units, green light emitting units, and blue light emitting units. The first light emitting units 1052 are traditional RGB light emitting units. The second light emitting units 1051 make the second sub-pixel 160 to emit light of red, green or blue.

The electron transport layer 106 is disposed on a side of the light emitting diode away from the hole transport layer 104.

The second electrode 107 is disposed on a side of the electron transport layer 106 away from the light emitting diode. The second electrode 107 is a cathode.

The encapsulation layer 108 is disposed on a side of the second electrode 107 away from the electron transport layer 106. The encapsulation layer 108 is configured to protect the display panel 100 and extend lifespan of the display panel 100.

With reference to FIG. 5, the present invention also provides a display device 200 includes the display panel 100 and a camera module 201. The camera module 201 is disposed under the display panel 100 and corresponds to the light transmissive displaying region 120. The display panel 100 is divided into the main displaying region 110 and the light transmissive displaying region 120. The main displaying region 110 employs the first rendering pixel units 130 to render pixels. Each of the first rendering pixel units 130 is assembled by the first sub-pixels 140 to make the main displaying region 110 to be able to display images. In the light transmissive displaying region 120, the second rendering pixel units 150 are employed to render pixels. Each of the second rendering pixel units 150 is assembled by the second sub-pixels 160 to make the light transmissive displaying region 120 to be able to display images such that the display device 200 an perform full screen displaying.

An area of the second sub-pixel 160 of the light transmissive displaying region 120 is less than an area of the first sub-pixel 140 of the main displaying region 110 such that a density of the second rendering pixel units 150 is less than a density of the first rendering pixel units 130, which allow light to better pass through the light transmissive displaying region 120 to be received by the camera module 201. The second rendering pixel units 150 in the light transmissive displaying region 120 are arranged in a RGB sub-pixel arrangement to mitigate a color shift issue due to a lowered density of pixels of the light transmissive displaying region 120.

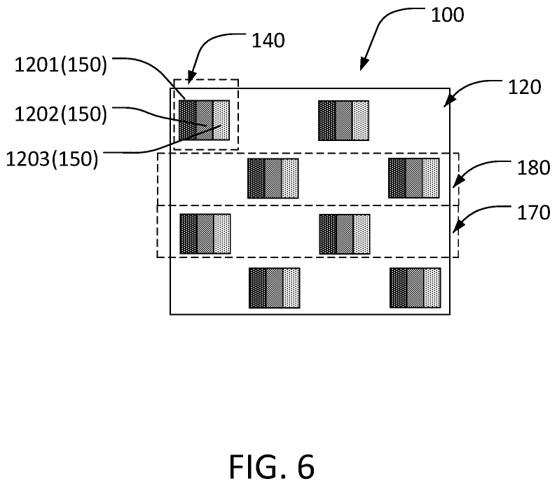

With reference to FIG. 6, the present invention also provides another embodiment, a difference of the another embodiment from the above embodiment is that, in another embodiment, the first rendering pixel units 130 are arranged in an array in the main displaying region 110. In the light transmissive displaying region 120, the second rendering pixel units 150 are arranged in an array to form at least two rows of the second rendering pixel units. The rows of the second rendering pixel units include odd rows of the second rendering pixel units 170 and even rows of the second rendering pixel units 180.

The odd rows of the second rendering pixel units 170 are constituted by a plurality of the second rendering pixel units 150. The even rows of the second rendering pixel units 180 are constituted by a plurality of the second rendering pixel units 150. The second rendering pixel units 150 of the odd rows of the second rendering pixel units 170 are arranged alternatively with the second rendering pixel units 150 of the even rows of the second rendering pixel units 170.

In another embodiment, an area of light transmittance is increased to make the density of the second rendering pixel units 150 to be less than the density of the first rendering pixel units 130 such that more light can pass through the light transmissive displaying region 120.

The present invention provides the display panel and the display device under the two different embodiments. One embodiment makes the area of the second sub-pixel 160 of the light transmissive displaying region 120 be less than the area of the first sub-pixel 140 of the main displaying region 110 such that the density of the second rendering pixel units 150 is less than the density of the first rendering pixel units 130, which makes light to better pass through the light transmissive displaying region 120 to be received by the camera module 201. Furthermore, the second rendering pixel units 150 in the light transmissive displaying region 120 employ the traditional RGB arrangement to mitigate the color shift issue due to the lowered density of the pixels of the light transmissive displaying region 120.

The other embodiment arranges the second rendering pixel units 150 of the odd rows of the second rendering pixel units 170 alternatively with the second rendering pixel units 150 of the even rows of the second rendering pixel units 170. The area of the second sub-pixel 160 is the same as the area of the first sub-pixel 140, which increases an area of light transmittance and makes the density of the second rendering pixel units 150 be less than the density of the first rendering pixel units 130 to increases light transmittance of the light transmissive displaying region 120. Therefore, the display device 200 can acquire better photographing effect.

The technical scope of the present invention is not limited to the contents of the description, and those skilled in the art can make various variants and modifications to the embodiment without departing from the technical idea of the present invention, and these variants and modifications should be within the scope of the present invention.

What is claimed is:

1. A display panel, comprising a light transmissive displaying region and a main displaying region, the main displaying region surrounding the light transmissive displaying region, and the display panel constituted by a plurality of rendering pixel units;
wherein the rendering pixel units comprise a plurality of first rendering pixel units disposed in the main displaying region and a plurality of second rendering pixel units disposed in the light transmissive displaying region;
wherein the first rendering pixel units employ a pentile arrangement to make the main displaying region illuminate and display; and
wherein the second rendering pixel units employ a traditional RGB arrangement to make the light transmissive displaying region illuminate and display.

2. The display panel as claimed in claim 1, wherein
in the main displaying region, each of the first rendering pixel units comprises at least one first sub-pixel; and
in the light transmissive displaying region, each of the second rendering pixel units comprises at least one second sub-pixel.

3. The display panel as claimed in claim 2, wherein
the first rendering pixel units are arranged in an array in the main displaying region;
the second rendering pixel units are arranged in an array in the light transmissive displaying region; and
an area of the first sub-pixel is greater than an area of the second sub-pixel.

4. The display panel as claimed in claim 1, wherein
a density of the second rendering pixel units is less than a density of the first rendering pixel units.

5. The display panel as claimed in claim 4, wherein
the first rendering pixel units are arranged in an array in the main displaying region;
in the light transmissive displaying region, the second rendering pixel units are arranged in an array to form at least two rows of the second rendering pixel units;
the rows of the second rendering pixel units comprise odd rows of the second rendering pixel units and even rows of the second rendering pixel units; and
the odd rows of the second rendering pixel units are arranged alternately with the even rows of the second rendering pixel units.

6. The display panel as claimed in claim 2, wherein
the first sub-pixel is one of a red sub-pixel, a green sub-pixel and a blue sub-pixel; and
the second sub-pixel is one of a red sub-pixel, a green sub-pixel, and a blue sub-pixel.

7. The display panel as claimed in claim 2, wherein
each of the second rendering pixel units comprises three second sub-pixels, which are a red sub-pixel, a green sub-pixel, and a blue sub-pixel.

8. The display panel as claimed in claim 2, wherein
each of the first rendering pixel units comprises two first sub-pixels, and each of the first rendering pixel units is disposed with a red sub-pixel and a green sub-pixel, or with a blue sub-pixel and the green sub-pixel, or with a blue sub-pixel and the red sub-pixel.

9. The display panel as claimed in claim 1, wherein
the display panel comprises:
a substrate;
a first electrode disposed on the substrate;
a hole injection layer disposed on a side of the first electrode away from the substrate;
a hole transport layer disposed on a side of the hole injection layer away from the first electrode;
a first light emitting diode disposed on a side of the hole transport layer away from the hole injection layer;
an electron transport layer disposed on a side of the first light emitting diode away from the hole transport layer;
a second electrode disposed on a side of the electron transport layer away from the light emitting diode; and
a first encapsulation layer disposed on a side of the second electrode away from the electron transport layer.

10. A display device, comprising the display panel as claimed in claim 1, wherein the display device further comprises a camera module, and the camera module is disposed under the display panel and corresponds to the light transmissive displaying region.
